(19) United States
(12) Patent Application Publication
(10) Pub. No.: US 2021/0108789 A1
(43) Pub. Date: Apr. 15, 2021

(54) Flexible LED Light Engine Interconnects

(71) Applicants: Nagaraja Chikkegowda, Andover, MA (US); Sivakumar Thangavelu, Westford, MA (US); Driss Baba, Swampscott, MA (US)

(72) Inventors: Nagaraja Chikkegowda, Andover, MA (US); Sivakumar Thangavelu, Westford, MA (US); Driss Baba, Swampscott, MA (US)

(73) Assignee: OSRAM SYLVANIA Inc., Wilmington, MA (US)

(21) Appl. No.: 17/062,709

(22) Filed: Oct. 5, 2020

Related U.S. Application Data
(60) Provisional application No. 62/913,348, filed on Oct. 10, 2019.

(51) Int. Cl. F21V 23/06; F21S 4/22; F21V 23/00; F21V 21/08

(52) U.S. Cl. CPC F21V 23/06; F21S 4/22; F21Y 2115/00; F21V 21/0808; F21V 23/004

(57) ABSTRACT

Systems and methods disclosed herein include a light engine circuit board including a flexible substrate having a first interconnect region located at a first end of the flexible substrate and a second interconnect region located at a second end of the flexible substrate, in which the first interconnect region and the second interconnect region each comprise one or more solder strips, and one or more LEDs on the flexible substrate.

### CROSS-REFERENCE TO RELATED APPLICATIONS

This application claims a benefit of priority under 35 U.S.C. § 119 to U.S. Provisional Application No. 62/913,348 filed on Oct. 10, 2019, which is fully incorporated herein by reference in its entirety.

### FIELD OF THE DISCLOSURE

This disclosure relates to light engines, and specifically to systems and methods for interconnecting flexible light emitting diode (LED) light engine printed circuit boards (PCBs).

### BACKGROUND

LEDs or other solid-state light sources may be placed on a variety of different surfaces, objects, or spaces depending on the application. Some of these surfaces or objects may be non-planar (e.g., curved). With the advent of flexible substrates, LEDs and LED light engines may be placed on a flexible PCB in order to attach to non-planar surfaces. However, given the large number of applications for flexible LED light engines it is difficult to custom design a flexible LED light engine to satisfy the size, length, and bend specifications for every particular application. What is needed are flexible LED light engines that are easily adapted to different size and bend constraints without losing reliability of operation.

### SUMMARY

Various implementations disclosed herein include a light engine circuit board that includes a flexible substrate, one or more LEDs on the flexible substrate, and one or more interconnect regions, each including one or more solder strips. Adjacent light engine circuit boards may be connected by overlapping an interconnect region of one circuit board with an interconnect region of the other circuit board so that the solder strips of the overlapping interconnect regions conduct electricity. The interconnect regions may allow angular bending (e.g., bending at right angles) or circular bending with a tight bending radius.

Further implementations disclosed herein include a light engine circuit board, including a flexible substrate having a first interconnect region located at a first end of the flexible substrate and a second interconnect region located at a second end of the flexible substrate, in which the first interconnect region and the second interconnect region each comprise one or more solder strips, and a plurality of light emitting diodes (LEDs) on the flexible substrate.

In some implementations, the first interconnect region is located on a top surface of the flexible substrate and the second interconnect region is located on a bottom surface of the flexible substrate. In some implementations, the one or more solder strips include two solder strips. In some implementations, the one or more solder strips are line shaped, T-shaped, or I-shaped. In some implementations, the one or more solder strips on the first interconnect region and the one or more solder strips on the second interconnect region are shaped and positioned in such a way as to overlap each other when the first end is placed on top of the second end. In some implementations, the first interconnect region and the second interconnect region are shaped to overlap each other when the first end is placed on top of the second end. In some implementations, the one or more solder strips are electrically coupled to the plurality of LEDs via one or more traces. In some implementations, the circuit board further includes an adhesive tape layer. In some implementations, the plurality of LEDs are electrically coupled to a power source, and when a portion of the light engine circuit board is cut, a remaining plurality of LEDs on the light engine circuit board are still electrically coupled to the power source.

Further implementations disclosed herein include a system, the system including a first light engine circuit board that includes a first flexible substrate having a first interconnect region located at a first end of the first flexible substrate, in which the first interconnect region comprises one or more solder strips and a plurality of light emitting diodes (LEDs) on the first flexible substrate, and a second light engine circuit board that includes a second flexible substrate having a second interconnect region located at a second end of the second flexible substrate, in which the second interconnect region comprises one or more solder strips and a plurality of LEDs on the second flexible substrate, in which the first interconnect region of the first light engine circuit board overlaps with the second interconnect region of the second light engine circuit board to provide an electrical connection between the first light engine circuit board and the second light engine circuit board.

In some implementations, the one or more solder strips on the first interconnect region and the one or more solder strips on the second interconnect region overlap when the first interconnect region overlaps the second interconnect region in order to provide the electrical connection. In some implementations, the first interconnect region is located on a top surface of the first flexible substrate and the second interconnect region is located on a bottom surface of the second flexible substrate. In some implementations, the first light engine circuit board may be angularly bent with respect to the second light engine circuit board at the location where the first interconnect region overlaps the second interconnect engine. In some implementations, the first light engine circuit board may be bent at a 90° angle with respect to the second light engine circuit board. In some implementations, the first light engine circuit board may be bent at an acute angle with respect to the second light engine circuit board. In some implementations, the first light engine circuit board and the second light engine circuit board are bent in an arc shape. In some implementations, the arc shape has a radius of curvature of 1 inch or greater. In some implementations, the arc shape has a radius of curvature between 1 inch and 6 inches. In some implementations, the arc shape has a radius of curvature that depends on at least one of a physical dimension of the plurality of LEDs, a number of LEDs per unit length of the first and second light engine circuit boards, and a thickness of one or more materials comprising the first and second light engine circuit boards.

### BRIEF DESCRIPTION OF THE DRAWINGS

FIG. 1 is a block diagram illustrating a flexible LED light engine PCB with interconnects in accordance with various implementations.

FIGS. 2A-2F are examples of different PCB interconnect designs in accordance with various implementations.

FIGS. 3A-3C are examples of different solder strip interconnects in accordance with various implementations.

FIGS. 4A-4B is a dimensional diagram of an example PCB interconnect design in accordance with various implementations.

FIGS. 5A-5C are examples of possible bend configurations of a flexible LED light engine with interconnects in accordance with various implementations.

These and other features of the present implementations will be understood better by reading the following detailed description, taken together with the figures herein described. The accompanying drawings are not intended to be drawn to scale. For purposes of clarity, not every component may be labeled in every drawing.

### DETAILED DESCRIPTION

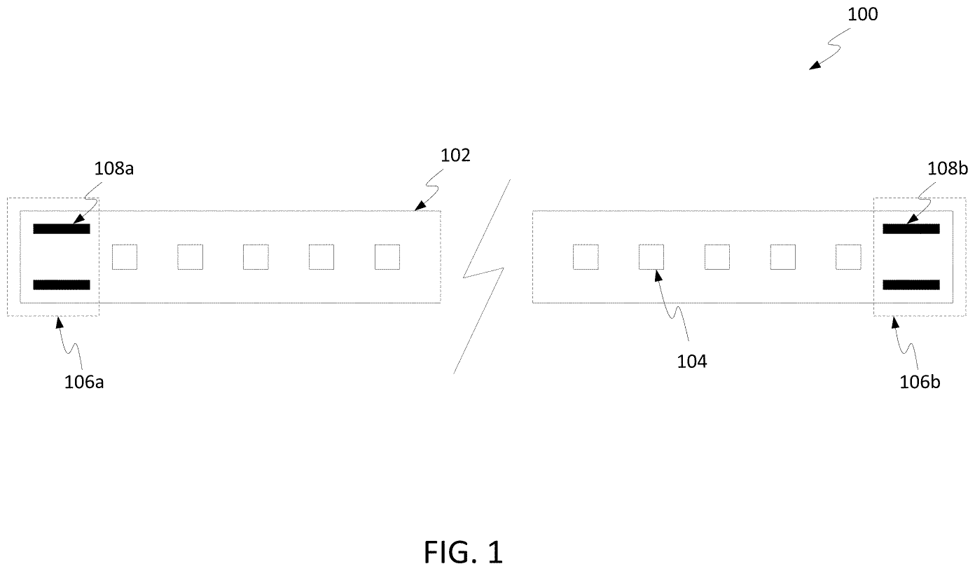

FIG. 1 is a block diagram illustrating a flexible LED light engine PCB 100 with interconnects in accordance with various implementations. The PCB 100 may include a flexible substrate 102. The flexible substrate 102 may be composed of, for example, a polyimide material. The flexible substrate 102 may include multiple layers, such as top and bottom conducting layers and a middle insulating layer. The PCB 100 may also include an adhesive layer (not shown in FIG. 1) that allows the PCB 100 to be attached to a particular surface. The PCB 100 may also include a number of LEDs 104, or other solid-state light sources. The number of LEDs in PCB 100 may vary depending on the length of the PCB 100. In some implementations, the PCB 100 may be cut to a particular length for a certain application without affecting the operability of the PCB 100.

The PCB 100 may also include interconnect regions 106a, 106b (jointly, 106). The interconnect regions 106 are used to connect multiple PCBs 100 together, to increase the length of the light engine to suit a particular application. The interconnection regions 106 each include one or more solder strips 108a, 108b (jointly, 108). The solder strips 108 provide conduction points so that power is conducted through the interconnect regions 106 to connected PCBs 100. In some implementations, the current carrying traces are located on the bottom layer of the PCB 100. In this case, the solder strips of the interconnect region on the bottom layer may be directly connected to the traces. The solder strips of the interconnect region on the top layer may be connected to the traces using a via from the bottom layer to the top layer.

For a given PCB 100, the interconnect region on one end of the PCB (e.g., 106a) is located on the top layer of the PCB 100 while the interconnect region on the other end of the PCB (e.g., 106b) is located on the bottom layer of the PCB 100. Thus, when the interconnect regions of adjacent PCBs are joined together, the top layer interconnect region of one PCB overlaps the bottom layer interconnect region of the other PCB. The solder strips 108 of overlapping interconnect regions also overlap such that when solder strips 108 are soldered together, they provide conduction points for traces connected to the solder strips 108. For example, the solder strips 108 may allow power to flow from one PCB to another PCB.

The interconnect regions 106 may be shaped to allow not only circular bending of multiple joined PCBs, but angular bending as well with less stress on the connection points so that PCB operation is not affect. For example, the interconnect regions 106 may be bent at a right angle, or an acute angle without losing conduction capability. The interconnect regions 106 may also enable circular bending at very high degrees (e.g., bends with a radius of curvature of 1-3 inches).

In the solder joining process, the interconnect regions of adjacent PCBs 100 may be soldered together through either an automated or manual solder process. Uniform heat is applied at top and bottom solder strips of adjacent PCBs to form a strong and reliable connection joint. The solder strips 108 may comprise copper pads that provide a path for conduction through the electrically insulating substrate to pads or traces on the other side of the PCB 100. The copper pads may be connected to copper conductors that carry current to components on the PCB 100. The copper conductors may function as a bus bar and may be thick enough to carry high currents. Copper conductors may be run on or under the insulating substrate for isolation, current carrying capacity, and protection. This method of attachment is highly effective in joining printed circuit strips into larger strips, arrays, and flex reels to be used in a variety of lighting applications.

Polyimide film is the most common insulating material used in flex circuitry. For example, thin board substrate polyimide adds flexibility to the connection, reducing stress at the solder joint associated with the use of solder strips. Staggered overlapping attachments of solder strips may prevent tearing of the solder strips on the PCB 100 when bending stresses are introduced. The thin board substrate materials and thicknesses also assist in handling solder melt temperatures without delamination or mutilation. The interconnect regions 106 and solder strips 108 of adjacent PCBs 100 may designed to match each other in shape, spacing, area, thermal features, and other attributes.

The interconnect regions 106 and the copper conductor/bus bar may be further protected from moisture by adding a thermal conductive insulating tape, which also helps in better thermal management. Commercially available adhesive transfer tapes suitable for use with PCB 100 may include models 3M 8810, 3M 468MPF and 9495MP. The interconnect regions 106 may also include a conformal coating on one side of the PCB to strengthen the joint and protect the solder strips 108 from exposure to outside elements. Thermal vias around the LEDs 104 may also be used to improve thermal management in the case of high-power LEDs.

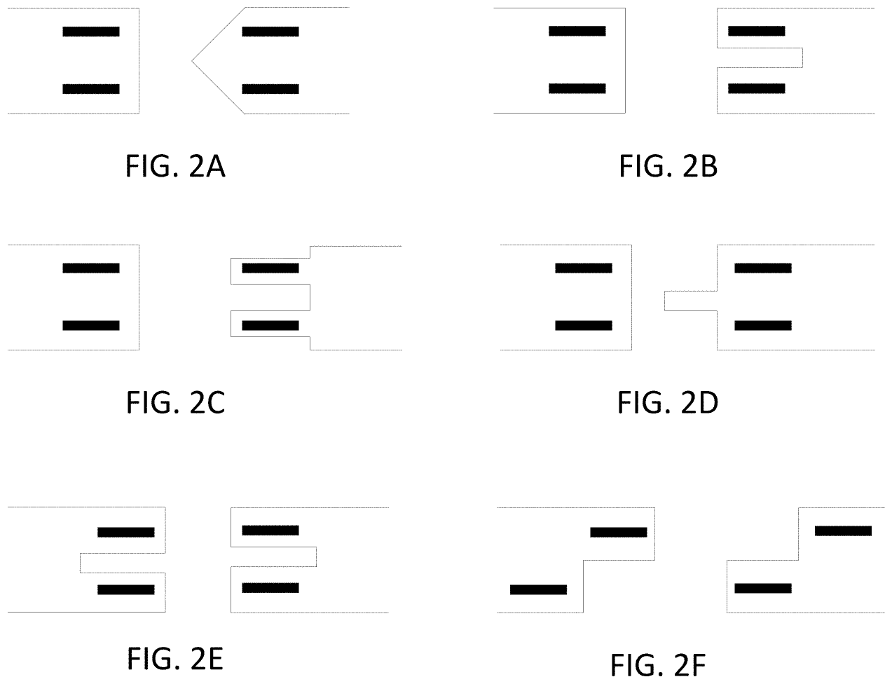

FIGS. 2A-2F show illustrative examples of various interconnect region shapes in accordance with various implementations, each of which enable the circular or angular bending qualities as described above. With respect to each of FIGS. 2A-2F, the left interconnect region is on one side (e.g., bottom layer) of a first PCB while the right interconnect region is on the other side (e.g., top layer) of a second, adjacent PCB such that the solder strips overlap when placed on top of each other. In some implementations, paired interconnect regions may be designed to fit only with each other, i.e., they are complementary shaped. For example, PCBs 100 that do not have paired or keyed interconnect regions may not be attached to each other. The shape and configuration of interconnect regions is not limited to those shown in FIGS. 1-2F, but may encompass any other suitable shape and configuration known to persons of ordinary skill in the art.

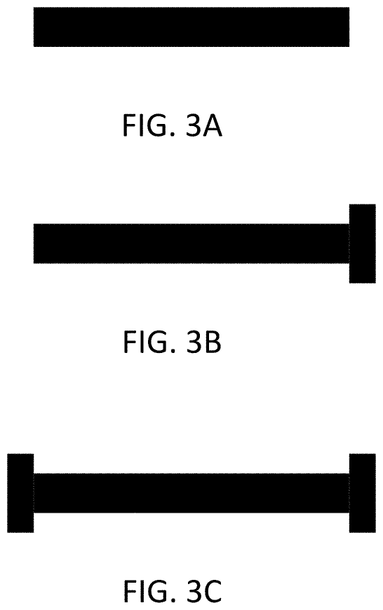

FIGS. 3A-3C show illustrative examples of various solder strip shapes in accordance with various implementations, each of which enable the circular or angular bending qualities as described above. For example, FIG. 3A illustrates a line-shaped solder strip, FIG. 3B illustrates a T-shaped solder strip, and FIG. 3C illustrates an I-shaped solder strip. The shape and configuration of solder strips is not limited to those shown in FIGS. 3A-3C, but may encompass any other suitable shape and configuration known to persons of ordinary skill in the art.

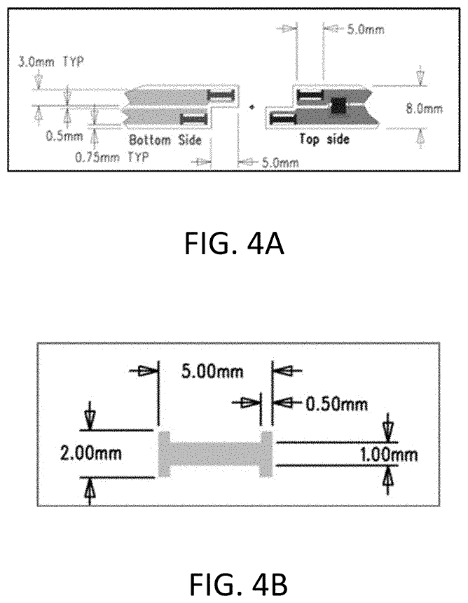

FIGS. 4A-4B show the dimensions of an example PCB interconnect design in accordance with various implementations. This interconnect design combines the interconnect region shape illustrated in FIG. 2F with the solder strip shape illustrated in FIG. 3C. Such a design may be advantageous for manual or semi-automated soldering processes as it allows easy alignment of the solder strips. For example, a long strip with cross-beams at both ends provide attachment strength in both the longitudinal and lateral axes of the PCB, and provide a singular orientation for attachment.

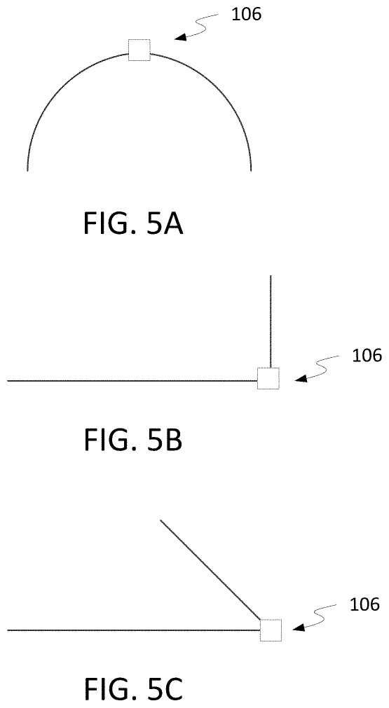

FIGS. 5A-5C are examples of possible bend configurations of a flexible LED light engine with interconnects in accordance with various implementations. For example, FIG. 5A shows that multiple LED light engines jointed using the disclosed interconnect design may achieve small bend radiuses when bent in an arc shape, for example up to bend radiuses of 1 inch. In general, the bend radius may be dependent on a number of factors, including but not limited to the physical dimension of LED, the number of LEDs per unit length of the light engine, and the thickness of various materials in the light engine (e.g., thermal adhesive tape, PCB copper thickness, polyimide material, glue used in construction of PCB stackup and PCB (single layer vs. multi-layer)). FIG. 5B shows that multiple LED light engines jointed using the disclosed interconnect design may be bent at right angles (i.e., 90 degrees) at the interconnect region 106 without affecting current conduction. FIG. 5C shows that multiple LED light engines jointed using the disclosed interconnect design may be bent at acute angles at the interconnect region 106 without affecting current conduction.

Unless otherwise stated, use of the word “substantially” may be construed to include a precise relationship, condition, arrangement, orientation, and/or other characteristic, and deviations thereof as understood by one of ordinary skill in the art, to the extent that such deviations do not materially affect the disclosed methods and systems.

Throughout the entirety of the present disclosure, use of the articles “a” and/or “an” and/or “the” to modify a noun may be understood to be used for convenience and to include one, or more than one, of the modified noun, unless otherwise specifically stated. The terms “comprising”, “including” and “having” are intended to be inclusive and mean that there may be additional elements other than the listed elements.

The foregoing description of the implementations of the present disclosure has been presented for the purposes of illustration and description. It is not intended to be exhaustive or to limit the present disclosure to the precise form disclosed. Many modifications and variations are possible in light of this disclosure. It is intended that the scope of the present disclosure be limited not by this detailed description, but rather by the claims appended hereto.

What is claimed is:

1. A light engine circuit board, comprising:
a flexible substrate having a first interconnect region located at a first end of the flexible substrate and a second interconnect region located at a second end of the flexible substrate, wherein the first interconnect region and the second interconnect region each comprise one or more solder strips; and
a plurality of light emitting diodes (LEDs) on the flexible substrate.

2. The light engine circuit board of claim 1, wherein the first interconnect region is located on a top surface of the flexible substrate and the second interconnect region is located on a bottom surface of the flexible substrate.

3. The light engine circuit board of claim 1, wherein the one or more solder strips comprise two solder strips.

4. The light engine circuit board of claim 1, wherein the one or more solder strips are line shaped, T-shaped, or I-shaped.

5. The light engine circuit board of claim 1, wherein the one or more solder strips on the first interconnect region and the one or more solder strips on the second interconnect region are shaped and positioned in such a way as to overlap each other when the first end is placed on top of the second end.

6. The light engine circuit board of claim 1, wherein the first interconnect region and the second interconnect region are shaped to overlap each other when the first end is placed on top of the second end.

7. The light engine circuit board of claim 1, wherein the one or more solder strips are electrically coupled to the plurality of LEDs via one or more traces.

8. The light engine circuit board of claim 1, further comprising an adhesive tape layer.

9. The light engine circuit board of claim 1, wherein:
the plurality of LEDs are electrically coupled to a power source; and
when a portion of the light engine circuit board is cut, a remaining plurality of LEDs on the light engine circuit board are still electrically coupled to the power source.

10. A system, comprising:
a first light engine circuit board, comprising:
a first flexible substrate having a first interconnect region located at a first end of the first flexible substrate, wherein the first interconnect region comprises one or more solder strips; and
a plurality of light emitting diodes (LEDs) on the first flexible substrate; and
a second light engine circuit board, comprising:
a second flexible substrate having a second interconnect region located at a second end of the second flexible substrate, wherein the second interconnect region comprises one or more solder strips; and
a plurality of LEDs on the second flexible substrate;
wherein the first interconnect region of the first light engine circuit board overlaps with the second interconnect region of the second light engine circuit board to provide an electrical connection between the first light engine circuit board and the second light engine circuit board.

11. The system of claim 10, wherein the one or more solder strips on the first interconnect region and the one or more solder strips on the second interconnect region overlap when the first interconnect region overlaps the second interconnect region in order to provide the electrical connection.

12. The system of claim 10, wherein the first interconnect region is located on a top surface of the first flexible substrate and the second interconnect region is located on a bottom surface of the second flexible substrate.

13. The system of claim 10, wherein the first light engine circuit board may be angularly bent with respect to the second light engine circuit board at the location where the first interconnect region overlaps the second interconnect engine.

14. The system of claim 13, wherein the first light engine circuit board may be bent at a 90° angle with respect to the second light engine circuit board.

15. The system of claim 13, wherein the first light engine circuit board may be bent at an acute angle with respect to the second light engine circuit board.

16. The system of claim 13, wherein the first light engine circuit board and the second light engine circuit board are bent in an arc shape.

17. The system of claim 13, wherein the arc shape has a radius of curvature of 1 inch or greater.

18. The system of claim 16, wherein the arc shape has a radius of curvature between 1 inch and 6 inches.

19. The system of claim 13, wherein the arc shape has a radius of curvature that depends on at least one of a physical dimension of the plurality of LEDs, a number of LEDs per unit length of the first and second light engine circuit boards, and a thickness of one or more materials comprising the first and second light engine circuit boards.
